(19) United States
(12) Patent Application Publication
(10) Pub. No.: US 2004/0166366 A1
(43) Pub. Date: Aug. 26, 2004

(54) Light-emitting fluorene-based copolymers, EL devices comprising the same and method of synthesis thereof

(76) Inventors: Nam-Sung Cho, Goyang-city (KR); Do-Hoon Hwang, Gumi-city (KR); Hong-Ku Shim, Daejeon (KR); Jong-Chul Kim, Daejeon (KR)

Correspondence Address: ROBERTS ABOKHAIR & MARDULA, SUITE 1000, 11800 SUNRISE VALLEY DRIVE, RESTON, VA, 20191, US

(21) Appl. No.: 10/780,042

(22) Filed: Feb. 17, 2004

(30) Foreign Application Priority Data
Aug. 16, 2001 (KR) 2001-0049386
Aug. 8, 2002 (WO) PCT/KR02/01514

(51) Int. Cl. H05B 33/14; C08G 61/12; C09K 11/06

(52) U.S. Cl. 428/690; 428/917; 313/504; 313/506; 257/40; 528/380

(57) ABSTRACT

Light-emitting copolymers and electroluminescence products made therefrom emitting a wavelength range from that of blue light to that of red light. The light-emitting copolymers are represented by the following Formula 1, in which the energy of blue light emission from a fluorene repeating unit on a blue light-emitting fluorene-based main chain is transferred to a red comonomer in the copolymer to emit red light.

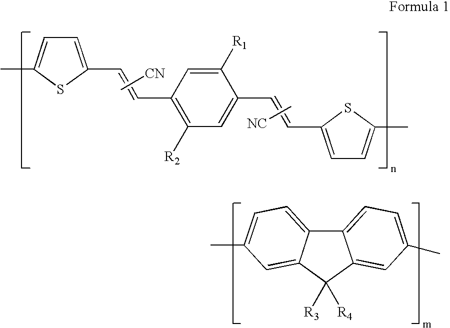

### CROSS REFERENCE TO OTHER PATENT APPLICATIONS

The present application claims the benefit of PCT Patent Application Ser. No. PCT/KR02/01514, filed 8 Aug. 2002, and Korean Patent Application 2001-0049386, filed 16 Aug. 2001, which are hereby incorporated by reference.

### BACKGROUND OF THE INVENTION

This invention relates to an improved method The present invention relates to a novel light-emitting copolymer capable of emitting not only blue light but also red light, characterized in that the energy of blue light released from a fluorene repeating unit on a blue light-emitting fluorene-based polymer as a main chain is transferred to a red comonomer present in the copolymer to emit red light; and an electroluminescence device comprising the same.

Much research for identifying polyfluorene-based conjugated copolymers used as light-emitting materials in EL devices has been performed since poly(9,9-dihexylfluorene) was reported as a blue light emitting polymer. The fluorene-based conjugated polymers have been noticed in light of their high photoluminescence (PL) and electroluminescence (EL) efficiencies, excellent thermal stability and superior solubility in various organic solvents. There has been effort to exhibit various colors based on the fluorene-based polymer.

In order to convert the color in the fluorene conjugated polymers, there are methods of doping green or red materials to the fluorene polymer and of copolymerizing comonomers having low energy band gaps. In the latter case, it is reported that, for yellow and green emission of Inbasekaran supplied by Dow Chemical Co., 5,5-dibromo-2,2-bithiophene and 4,7-dibromo-2,1,3-benzothiazol are copolymerized to the fluorene main chain. Additionally, it is reported by Lee et al. of IBM Co. that 3,9(10)-dibromopherylene, 4,4-dibromo-α-cyanostylbene and 1,4-bis(2-(4-bromophenyl)-1-cyanovinyl)-2-(2-ethylhexyl)-5-methoxybenzene are copolymerized with fluorene. Such fluorene-containing copolymers can exhibit yellow or green luminescence, as well as blue, even though small amounts thereof are used. But no electroluminescence devices using fluorene-based copolymers capable of emitting red light have been reported yet.

To overcome the above problems, the present inventors developed light-emitting copolymers, capable of emitting light in the wavelength range from blue up to red by using a fluorene-based conjugated polymer and introducing a comonomer having a low energy band gap prepared from various functional groups to a fluorene main chain via copolymerization.

### BRIEF SUMMARY OF THE INVENTION

An improved method for manufacturing It is an object of the present invention to provide a novel light-emitting fluorene-based copolymer, which emits red light due to various comonomers having low band gaps introduced to a blue light-emitting fluorene conjugated homopolymer with high photoluminescence and electroluminescence.

The present invention comprises light-emitting copolymers, capable of emitting light in the wavelength range from blue up to red. Said copolymers comprise a fluorene-based conjugated copolymer with a comonomer having a low energy band gap prepared from various functional groups to a fluorene main chain via copolymerization.

It is another object of the present invention to provide an electroluminescence device comprising such a light-emitting copolymer used as a light-emitting layer.

Based on the present invention, a light-emitting copolymer represented by the following formula 1 is characterized in that a comonomer comprising a nitrile functional group introduced to a thiophene backbone and an arylene backbone connected via an ethylene bridge, is connected with a fluorene backbone through a single bond, yielding a completely conjugated structure.

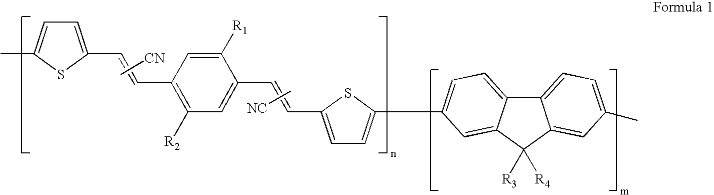

wherein, R₁ and R₂ represent silyl groups, alkyl groups or alkoxy groups; and R₃ and R₄ represent alkyl groups. Preferably, R₁, R₂, R₃ and R₄ contain C₁ to C₂₂ linear or branched alkyl groups.

In reference to Formula 1, preferred embodiments of the present invention that exhibit excellent light-emitting effects have a ratio of n/m, from 17.5/82.5 to 1.4/98.6.

### BRIEF DESCRIPTION OF THE DRAWINGS

FIG. 1 is a schematic diagram showing the electroluminescence device configuration according to the present invention;

FIG. 2 is a graph showing UV absorption spectra of the light-emitting copolymers of the present invention;

FIG. 3 is a graph showing PL emission spectra of the light-emitting copolymers of the present invention;

FIG. 4 is a graph showing EL emission spectra of the light-emitting copolymers of the present invention;

FIG. 5 is a graph showing a voltage-current characteristic curve of the EL device using the light-emitting copolymers of the present invention; and

FIG. 6 is a graph showing a voltage-EL intensity characteristic curve of the EL device using the light-emitting copolymers of the present invention.

### DETAILED DESCRIPTION OF THE INVENTION

Based on the present invention, a light-emitting copolymer represented by the following formula 1 is characterized in that a comonomer comprising a nitrile functional group introduced to a thiophene backbone and an arylene backbone connected via an ethylene bridge, is connected with a fluorene backbone through a single bond, yielding a completely conjugated structure.

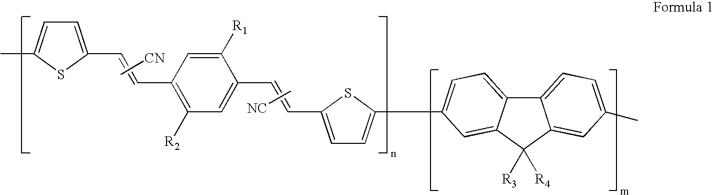

wherein, R₁ and R₂ represent silyl groups, alkyl groups or alkoxy groups; and R₃ and R₄ represent alkyl groups. Preferably, R₁, R₂, R₃ and R₄ contain C₁ to C₂₂ linear or branched alkyl groups.

In the formula 1, a ratio of n/m, which is not specifically limited, ranges from 17.5/82.5 to 1.4/98.6, to exhibit excellent light-emitting effects.

The light-emitting copolymer of the present invention can be obtained by copolymerizing a monomer 1 represented by the following formula 2 and another monomer 2 represented by the following formula 3 in the presence of nickel(0) catalyst.

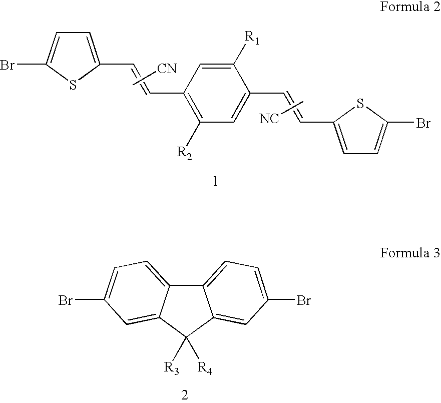

The light-emitting copolymer of the present invention has a completely conjugated structure comprising the monomers 1 and 2. The fluorene backbone can exhibit excellent luminous efficiency, and the polymer backbone of the formula 1 accepts the energy transferred from the fluorene backbone and emits light in the wavelength range from blue to red, according to the addition ratio of the comonomer 1. Such an emission is performed by transferring the energy from the fluorene backbone having a high energy band gap to the comonomer 1 backbone having a relatively low band gap. Under control of the addition ratio of the comonomer 1, such a comonomer is introduced to a conventional blue light emitting polymer, to give the fluorene-based copolymer capable of emitting not only blue light but also red light.

A description will be given of the production method of the light-emitting copolymer of the present invention, below.

It is noted that an alkoxy group substituted monomer represented by the following formula 4 is set forth to illustrate the comonomer represented by the formula 2, for convenience, but is not to be construed to limit the present invention.

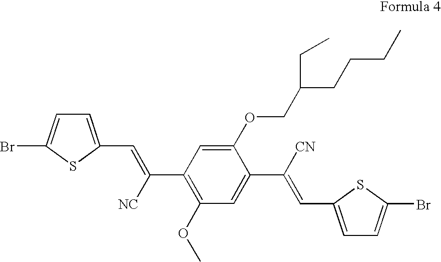

The dialkoxy group substituted compound represented by the above formula 4 (in the case that R₁ is methoxy group and R₂ is 2-ethylhexyloxy group) is prepared as follows.

As shown in the following Reaction Scheme 1,4-methoxyphenol is alkylation-reacted with 2-ethylhexyl bromide using potassium hydroxide as a base.

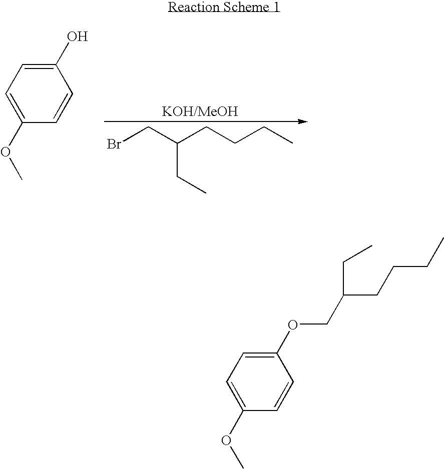

As shown in the following Reaction Scheme 2, (2-ethylhexyloxy)-4-methoxybenzene prepared from the reaction scheme 1 is subjected to chloromethylation using formaldehyde solution and hydrochloric acid/sulfuric acid, to yield 1,4-bis(chloromethyl)-2-(2-ethylhexyloxy)-5-methoxybenzene.

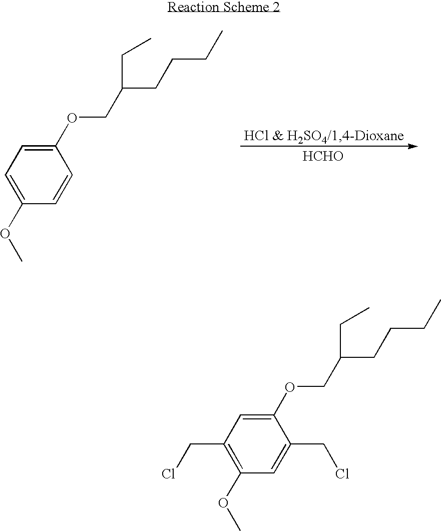

As in the following Reaction Scheme 3,1,4-bis(chloromethyl)-2-(2-ethylhexyloxy)-5-methoxybenzene, obtained from the above reaction scheme 2, is reacted with sodium cyanide, to yield 1,4-bis(cyanomethyl)-2-(2-ethylhexyloxy)-5-methoxybenzene.

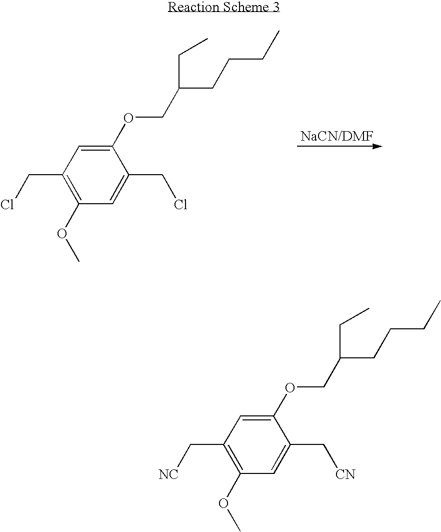

As in the following Reaction Scheme 4,1,4-bis(cyanomethyl)-2-(2-ethylhexyloxy)-5-methoxybenzene produced from the above reaction 3 is reacted with 5-bromothiophene-2-carbaldehyde via Knoevenagel reaction, to prepare 2,5-bis-{2-(4-bromothienyl)-1-cyanovinyl}-2-(2-ethylhexyloxy)-5-methoxybenzene.

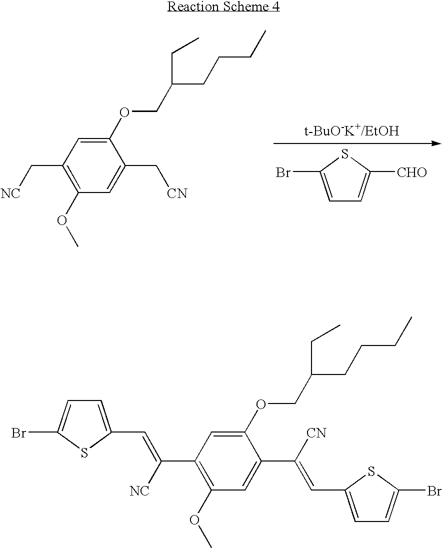

As in the following Reaction Scheme 5,2,7-dibromofluorene and 2-ethylhexyl bromide are reacted in toluene and sodium hydroxide in 50 wt % distilled water in the presence of a small amount of tetrabutylammonium bromide as a phase transfer catalyst at 80° C., to prepare 2,7-dibromo-9,9-bis(2-ethylhexyl)fluorene monomer.

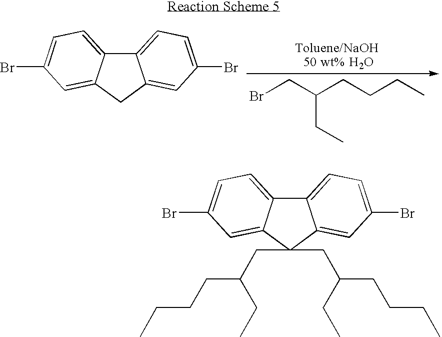

As the monomer 1 used in preparation of the light-emitting copolymer of the present invention, preparation of the compound of the formula 2 is illustrated. However, it is easily understood by those skilled in this art that other compounds, corresponding to the monomer of the present invention, can be also prepared in the same or similar manner as in the above method.

In preparation of the inventive light-emitting copolymer, the monomer 1 of the formula 2 and the monomer 2 of the formula 3 are reacted in the presence of nickel(0) catalyst to produce the copolymer as shown in the following reaction scheme 6, in which R₁ and R₂ represent silyl groups, alkyl groups or alkoxy groups, and R₃ and R₄ represent alkyl groups.

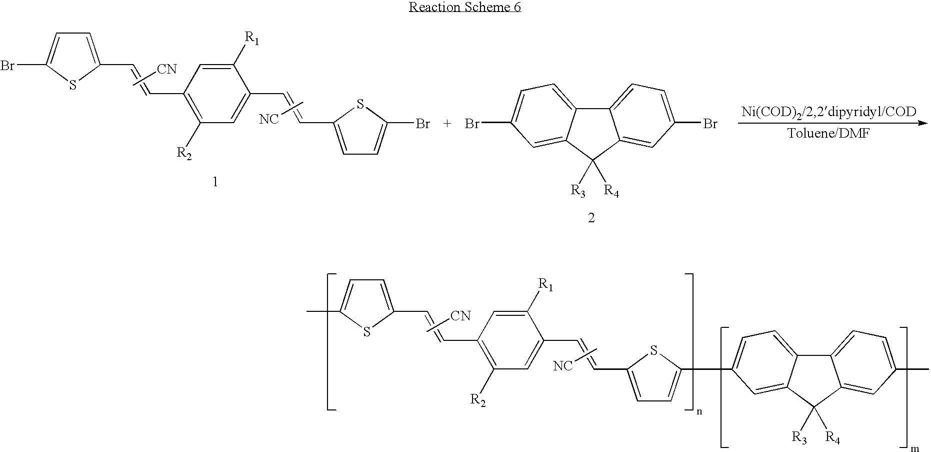

More specifically, as shown in the following Reaction Scheme 7, the monomer (formula 4) in which R₁ is an ethylhexyloxy group and R₂ is a methoxy group is reacted with 2,7-dibromo-9,9-bis(2-ethylhexyl)fluorene in which R₃ and R₄ are ethylhexyl groups, in the presence of nickel(0) catalyst, to produce poly{9,9-bis(2′-ethylhexyl)fluorene-2,7-diyl-co-2,5-bis(2-thienyl-1-cyanovinyl)-1-(2′-ethylhexyloxy)-4-methoxybenzene-5″,5″-diyl} (hereinafter, abbreviated to PFTCVB) as the light-emitting copolymer of the present invention.

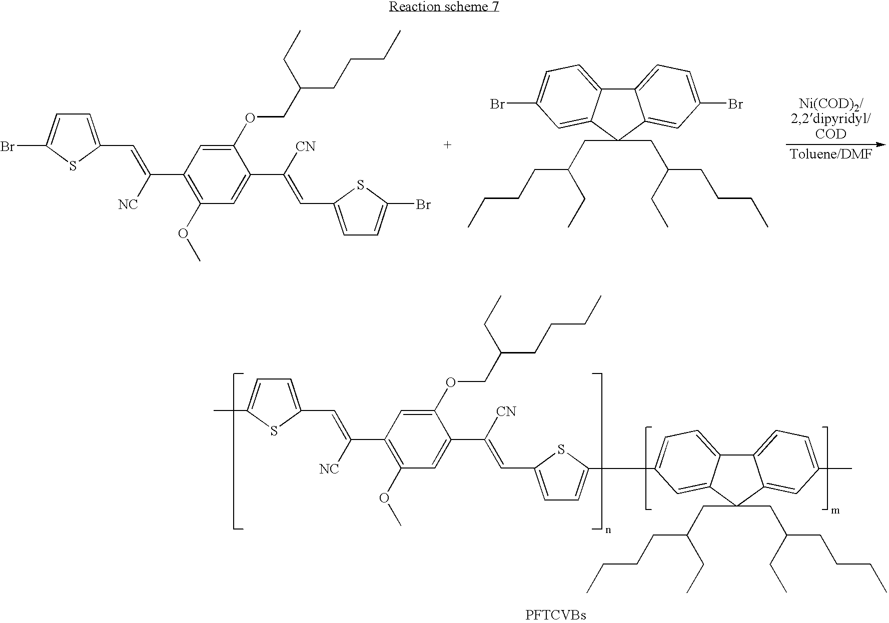

Thusly prepared light-emitting copolymer has an irregularly repeated structure of a fluorene unit and a monomeric unit having a low energy band gap.

As the monomeric unit having low band gap is contained in the polymer main chain in large numbers, the fluorene polymer can emit red light, as well as blue light. The reason is that the energy is released at the monomeric unit having the low energy band gap while being shifted on the conjugated main chain, thus emitting red light.

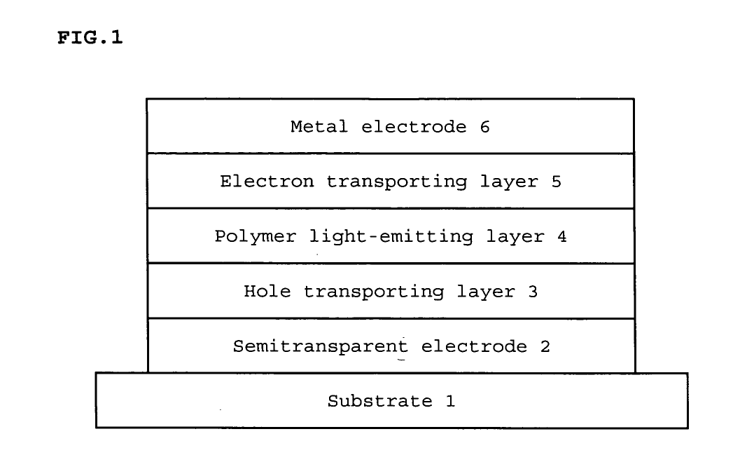

Referring to FIG. 1, there is shown the electroluminescence (EL) device comprising the light-emitting copolymer of the present invention.

The EL device of the present invention comprises a semitransparent electrode 2, a hole transporting layer 3, a polymer light-emitting layer 4, an electron transporting layer 5 and a metal electrode 6 successively laminated on a substrate 1. In addition, the EL device of the present invention can be formed to a simple single-layer structure comprising the semitransparent electrode 2, the polymer light-emitting layer 4 and the metal electrode 6 on the substrate. As the polymer light-emitting layer 4, the light-emitting copolymer prepared as mentioned above is used. As such, the polymer light-emitting layer can be formed only by use of the light-emitting copolymer and by blending such a copolymer with an electron or a hole transporting polymer such as PVK (polyvinylcarbazole).

Having generally described this invention, a further understanding can be obtained by reference to certain specific examples that are provided herein for purposes of illustration only and are not intended to be limiting unless otherwise specified.

### EXAMPLE 1

### Preparation of 4-(2-ethylhexyloxy)-1-benzene

20.0 g of 4-methoxyphenol (0.016 mol) and 12.8 g of KOH (1.2 eq) were dissolved in methanol, and added with 41 ml of 2-ethylhexyl bromide (1.3 eq), followed by reacting the solution at 80° C. for 12 hours. After completion of the reaction, the reaction solution was extracted with methylene chloride and distilled under reduced pressure, to give the title compound as an intermediate (30.0 g, 79%).

¹H-NMR (CDCl₃, ppm) δ 6.8 (s,4H), 3.8 (d,2H), 3.7 (s,3H), 1.6-1.2 (m,9H), 0.9 (m,6H). Anal. Calcd for C₁₅H₂₄O₂: C, 76.22; H, 10.26. Found: C, 75.11; H, 10.23.

### EXAMPLE 2

### Preparation of 1,4-bis(chloromethyl)-5-(2-ethyl hexyloxy)-2-methoxybenzene

30.0 g (0.13 mol) of the reaction intermediate obtained from the above example 1, excess HCl and HCHO were dissolved in 1,4-dioxane and reacted at 90° C. for 24 hours. During the reaction, 2-3 ml of sulfuric acid was added 3 or 4 times. After the reaction was completed, the reaction solution was extracted with methylene chloride, crystallized from hexane and filtered, to give 30.0 g (71%) of the title compound.

¹H-NMR (CDCl₃, ppm) δ 6.8 (d,2H), 4.5 (s,4H), 3.8 (d,2H), 3.7 (s,3H), 1.6-1.3 (m,9H), 0.9 (m,6H). Anal. Calcd for C₁₇H₂₆O₂Cl₂: C, 61.26; H, 7.88. Found: C, 60.89; H, 7.57.

### EXAMPLE 3

### Preparation of 1,4-bis(cyanomethyl)-5-(2-ethylhexyloxy)-2-methoxybenzene

10.0 g (0.03 mol) of the reaction intermediate obtained from the above example 2 was dissolved in N,N-dimethylformamide (DMF), added with 4.4 g (3 eq) of sodium cyanide and reacted at 45° C. for 72 hours. After the reaction was completed, the reaction solution was extracted with methylene chloride, and the obtained crystals were recrystallized from hexane, to give 5.7 g (60%) of the title compound.

¹H-NMR (CDCl₃, ppm) δ 6.90 (d,2H), 3.85 (d,2H), 3.83 (s,2H), 3.68 (s,4H), 1.72 (m,1H), 1.55-1.29 (m,8H), 0.91(q,6H). Anal. Calcd for C₁₉H₂₆N₂O₂; C, 72.58; H, 8.33; N, 8.91. Found; C, 72.52; H, 8.11; N, 8.67.

### EXAMPLE 4

### Preparation of 2,5-bis-{2-(4-bromothienyl)-1-cyanovinyl}-2-(2-ethylhexyloxy)-5-methoxybenzene

10 g (0.032 mol) of 1,4-bis(cyanomethyl)-5-(2-ethylhexyloxy)-2-methoxybenzene obtained from the above example 3, 18.5 g of 5-bromothiophene-2-carbaldehyde and a catalytic amount of potassium t-butoxide were added to 100 ml of methanol and reacted at room temperature for 48 hours. The resulting yellow solid was filtered and dried. Such a solid was washed with methanol several times, purified, filtered and dried, to give 62% yield (13.1 g) of the title compound as a desired monomer.

¹H-NMR(CDCl₃,ppm) 7.95(s,1H), 7.79(s,1H), 7.31(d,1H), 7.28(d,1H), 7.10(s,2H), 7.08(s,1H), 7.06(s,1H) 3.82(d,2H), 3.76(s,3H), 3.68(s,4H), 1.70-0.86(m,15H). Anal. Calcd for C₂₉H₂₈Br₂N₂O₂S₂; C, 52.74; H, 4.27; N, 4.24; S, 9.71. Found; C, 52.72; H, 4.10; N, 4.53; S, 9.84.

### EXAMPLE 5

### Preparation of 2,7-dibromo-9,9-bis(2-ethylhexyl)fluorene

10 g (0.03 mol) of 2,7-dibromofluorene, 17.3 g (3 eq) of 2-ethylhexylbromide were added to 100 ml of toluene and 100 ml of 50 wt % aqueous sodium hydroxide solution, and reacted at 60° C. for 48 hours. The resultant product was extracted with methylene chloride and water. While the organic layer was separated, the remaining water was removed over magnesium sulfate. The solvent was eliminated on a rotary evaporator, and the product was decolored using column chromatography. The resulting compound was concentrated, covered with ethanol and stored in a refrigerator, giving 62% yield (10.3 g) of a white solid product.

¹H-NMR(CDCl₃,ppm) 7.51(s,2H), 7.46(d,2H), 7.41(s,2H), 1.92(d,4H), 1.1-0.3(m,30H). Anal. Calcd for C₂₉H₄₀Br₂; C, 63.51; H, 7.35. Found; C, 61.01H, 7.19.

### EXAMPLE 6

### Preparation of Light-Emitting Copolymer

To prepare light-emitting copolymers, a total 0.0018 mol of 2,7-dibromo-9,9-bis(2-ethylhexyl)fluorene monomer and 2,5-bis-{2-(4-bromothienyl)-1-cyanovinyl}-2-(2-ethylhexyloxy)-5-methoxybenzene monomer were used. As such, 2,5-bis-{2-(4-bromothienyl)-1-cyanovinyl}-2-(2-ethylhexyloxy)-5-methoxybenzene monomer was used in various amounts. Copolymerization reactions were performed in Shrenk tubes, and a catalyst Ni(cyclooctadiene)₂ and 2,2-dipyridyl were dissolved in 5 ml of anhydrous N,N-dimethylformamide (DMF). A small amount of cyclooctadiene was added thereto, and the monomers were dissolved in 5 ml of absolute toluene and reacted for 3 days and nights. For end-capping, a small amount of 9-bromoanthracene was dissolved in absolute toluene, and after 24 hours, the copolymers were obtained using methanol/acetone/hydrochloric acid mixtures. Purification of the copolymers was performed through recrystallization and extraction using a Soxhlet extractor.

The above reaction is the same as in the reaction scheme 7.

The prepared light-emitting copolymers can be dissolved in an organic solvent, which have the number average molecular weight of 22,000-13,000 and the dispersion degree of 1.5-2.7. The polymerization result is summarized in the following Table 1.

TABLE 1

| | Copolymer | | | |
|---|---|---|---|---|
| | PFTCVB 1 | PFTCVB 3 | PFTCVB 5 | PFTCVB 15 |
| Mass | 47,000 | 23,000 | 33,000 | 61,000 |
| Average MW | | | | |
| Number | 20,000 | 15,000 | 13,000 | 22,000 |
| Average MW | | | | |
| Dispersion | 2.3 | 1.5 | 2.5 | 2.7 |
| Degree | | | | |
| (Mw/Mn) | | | | |
| Yield (%) | 72 | 66 | 75 | 61 |
| n Ratio (%) | 1.4 | 3.1 | 7.0 | 17.5 |

Note:
n ratio: calculated on a basis of nitrogen through element analysis

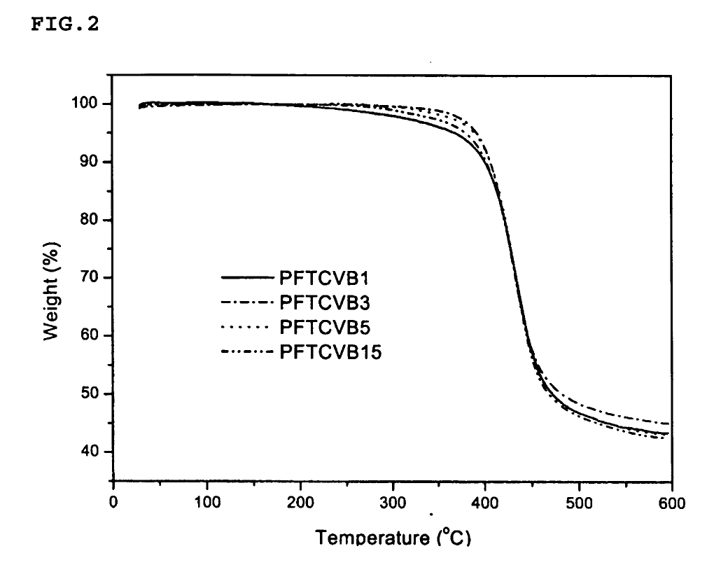

UV and photoluminescence measurements were performed on a film obtained by dissolving a small amount of the synthesized copolymers in chloroform and coating such a solution on quartz plate via a well-known spin coating method. UV maximum absorption wavelength in film phase was shown at 380 nm and an absorption band of long wavelength range was increased as the addition ratio of the comonomer 1 was raised (FIG. 2).

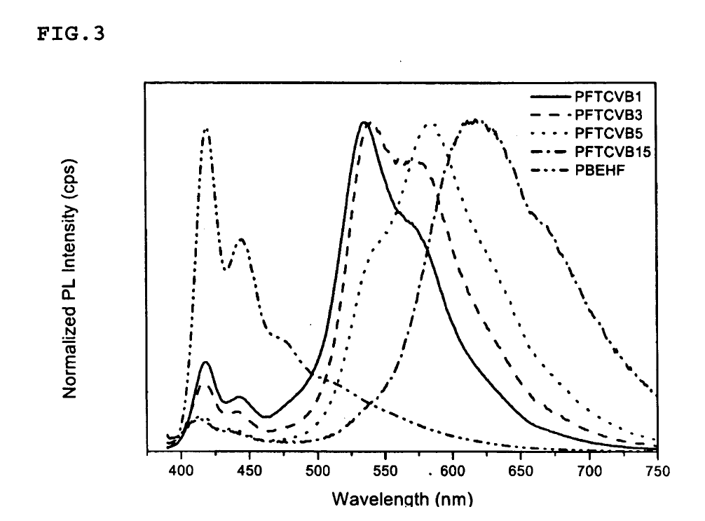

The film phase copolymers were measured for PL spectra, and PL λₘₐₓ was shifted to red light range as the addition ratio of the comonomer 1 was increased. In this regard, addition of 1% comonomer resulted in λₘₐₓ shifted to 420 nm and considerable decrease of a short wavelength, that is to say, a blue light emission range. Meanwhile, the addition of 15% comonomer led to λₘₐₓ shifted to 620 nm, nearly invisible at the blue wavelength range. This result is confirmed in FIG. 3.

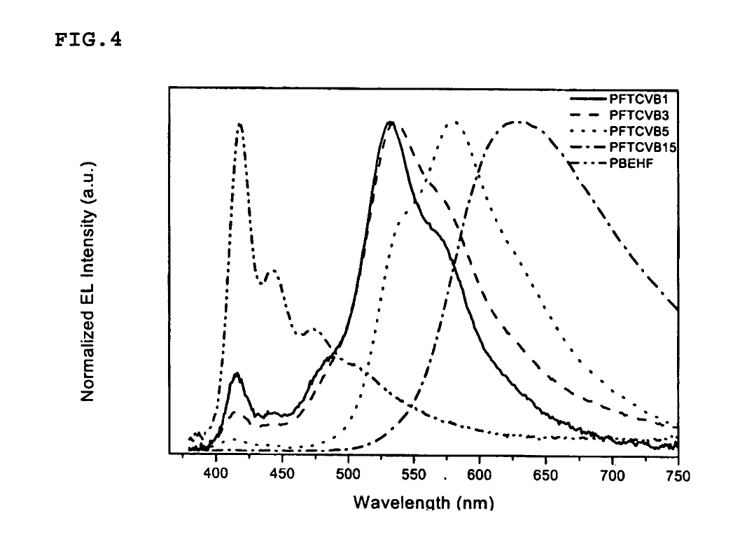

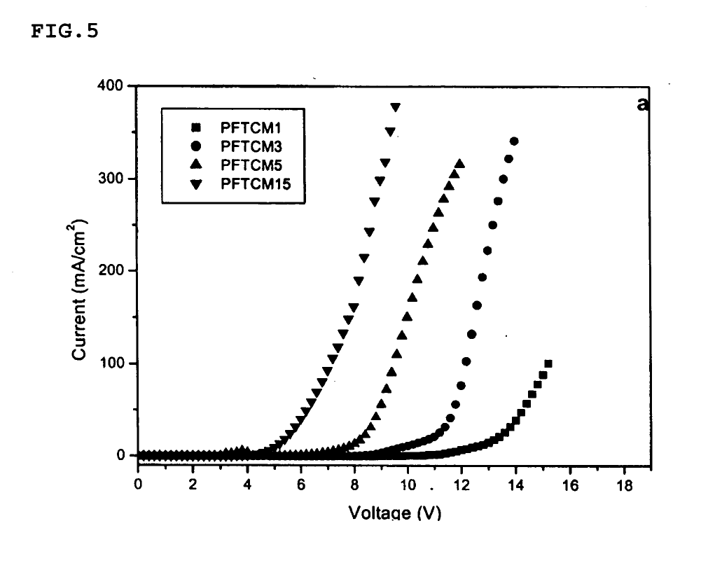

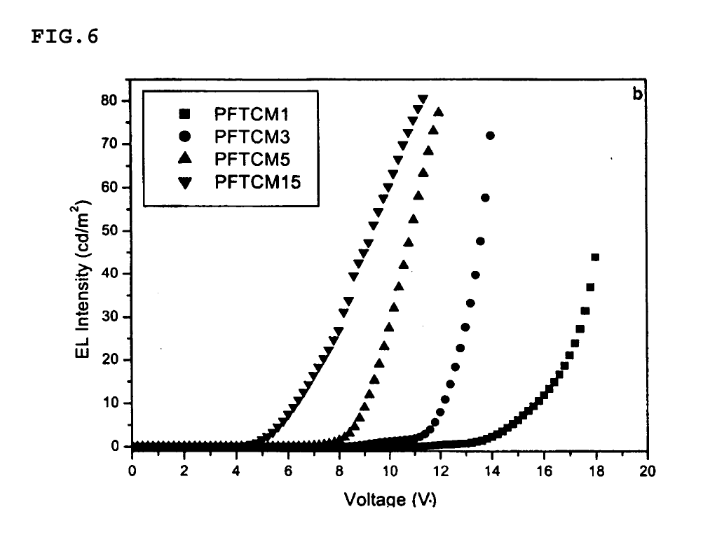

The electroluminescence device containing the light-emitting copolymer prepared from the above example 6 as a light-emitting layer was fabricated. A layer of PEDOT/PSS spin coated, a 100 nm light-emitting layer, a lithium fluoride (LiF) layer, and an Al layer used as a cathode of 500 nm thickness, in order, were laminated on a commercially available 100 nm thick ITO on a glass substrate, to fabricate such a device. The EL spectrum of the device is shown in FIG. 4, voltage-current characteristic in FIG. 5 and voltage-EL intensity characteristic in FIG. 6.

Further, it was confirmed that PL spectrum showed a similar appearance to EL spectrum. In other words, as the addition ratio of the comonomer 1 was increased, the blue light-emitting fluorene homopolymer began to emit red light. In particular, addition of 15% comonomer resulted in λₘₐₓ of 630 nm, reaching the red light wavelength range. This indicates that the energy is shifted from the fluorene unit of high band gap to the monomeric unit of low band gap, and released at such a low band gap unit.

The spectrum results are presented in the following Table 2, in which PL quantum efficiency is expressed as a relative value when the quantum efficiency of the fluorene homopolymer is 1.

TABLE 2

| | λmax (nm) | | | PL Quantum Efficiency |
|---|---|---|---|---|
| Copolymer | UV Absorption | PL | EL | (solution) |
| PBEHF | 380 | 420 | 419 | 1 |
| PFTCVB1 | 380 | 536 | 532 | 0.87 |
| PFTCVB3 | 380 | 544 | 535 | 0.71 |
| PFTCVB5 | 380 | 583 | 580 | 0.64 |
| PFTCVB15 | 380 | 620 | 630 | 0.43 |

### INDUSTRIAL APPLICABILITY

As described above, introduction of a comonomer having low energy band gap to a conventional fluorene homopolymer allows preparation of the copolymer capable of showing full colors from blue to red, and of the electroluminescence device containing such a copolymer as a light-emitting layer. As for the light-emitting copolymer of the present invention, the ratio of the comonomer 1 introduced to the fluorene main chain is controlled, whereby colors of the range difficult to obtain from the homopolymer, in particular, red, can be emitted.

The present invention has been described in an illustrative manner, and it is to be understood that the terminology used is intended to be in the nature of description rather than of limitation. Many modifications and variations of the present invention are possible in light of the above teachings. For example, other methods are possible in producing the copolymers. Therefore, it is to be understood that the scope of the invention is only to be limited by the following claims and equivalents thereof:

What is claimed is:

1. A light-emitting copolymer represented by the following formula 1: 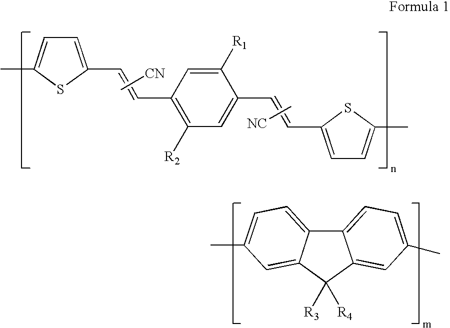
wherein R₁ and R₂ represent silyl groups, alkyl groups or alkoxy groups; and R₃ and R₄ represent alkyl groups.

2. The copolymer as defined in claim 1, wherein R₁, R₂, R₃ and R₄ contain C₁ to C₂₂ linear or branched alkyl groups.

3. The copolymer as defined in claim 1, wherein a ratio of n/m ranges from 17.5/82.5 to 1.4/98.6.

4. A comonomer represented by the following formula 2 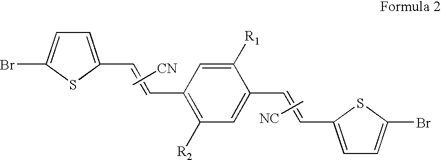
wherein R₁ and R₂ represent silyl groups, alkyl groups or alkoxy groups.

5. The comonomer as defined in claim 4, wherein R₁ and R₂ contain C₁ to C₂₂ linear or branched alkyl groups.

6. An electroluminescence device comprising a polymer light-emitting layer formed with the light-emitting copolymer of any one of claim 1.

7. The device as defined in claim 6, wherein the device is a multi-layer film structure comprising a semitransparent electrode, a hole transporting layer, the polymer light-emitting layer, an electron transporting layer and a metal electrode successively laminated on a substrate.

8. The device as defined in claim 6, wherein the polymer light-emitting layer is formed by blending the light-emitting copolymer with an electron or a hole transporting polymer.

9. A method of preparing the light-emitting copolymer of claim 1, comprising the step of copolymerizing a monomer represented by the following formula 2 and another monomer represented by the following formula 3 in the presence of nickel(0) catalyst: 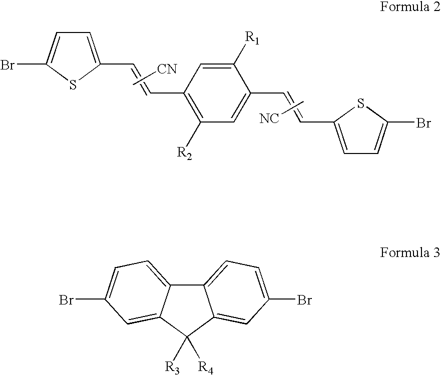
wherein R₁ and R₂ represent silyl groups, alkyl groups or alkoxy groups; and R₃ and R₄ represent alkyl groups.

10. The method as defined in claim 9, wherein R₁, R₂, R₃ and R₄ contain C₁ to C₂₂ linear or branched alkyl groups.

11. The light-emitting copolymer poly{[9,9-bis(2′-ethylhexyl)fluorene]ₘ-[2,7-diyl-co-2,5-bis(2-thienyl-1-cyanovinyl)-1-(2′-ethylhexyloxy)-4-methoxybenzene-5″,5″-diyl]ₙ}.

12. The copolymer as defined in claim 11, wherein a ratio of n/m ranges from 17.5/82.5 to 1.4/98.6.

13. The comonomer 2,5-bis-{2-(4-bromothienyl)-1-cyanovinyl}-2-(2-ethylhexyloxy)-5-methoxybenzene.

14. An electroluminescence device comprising a polymer light-emitting layer formed with the light-emitting copolymer of claims 13.

15. The device as defined in claim 14, wherein the device is a multi-layer film structure comprising a semitransparent electrode, a hole transporting layer, the polymer light-emitting layer, an electron transporting layer and a metal electrode successively laminated on a substrate.

16. The device as defined in claim 15, wherein the polymer light-emitting layer is formed by blending the light-emitting copolymer with an electron or a hole transporting polymer.
